(19) United States
(12) Patent Application Publication
(10) Pub. No.: US 2026/0301825 A1
(43) Pub. Date: Oct. 1, 2026

(54) READ RETRY SYSTEM AND METHOD FOR MEMORY DEVICES

(71) Applicant: SK hynix Inc., Gyeonggi-do (KR)

(72) Inventors: Fan ZHANG, San Jose, CA (US); Pengfei HUANG, San Jose, CA (US)

(21) Appl. No.: 19/096,527

(22) Filed: Mar. 31, 2025

(51) Int. Cl. G11C 16/26; G06F 12/02; G11C 16/04

(52) U.S. Cl. CPC G11C 16/26; G06F 12/0246; G11C 16/0483

(57) ABSTRACT

A system which performs read retry operations for a memory device. The system includes a controller which performs multiple read operations on the data of the at least one page using a set of read voltages which includes a center read voltage and neighboring read voltages adjacent to the center read voltage, determines fail bit counts (FBCs) for the set of read voltages, determines gradients of FBCs between the center read voltage and the neighboring read voltages based on the determined FBCs, and adjusts the neighboring read voltages and the center read voltage based on the gradients of FBCs to generate a set of adjusted read voltages including adjusted neighboring and center read voltages.

### BACKGROUND

### 1. Field

Embodiments of the present disclosure relate to a scheme for a read operation of a memory system.

### 2. Description of the Related Art

The computer environment paradigm has shifted to ubiquitous computing systems that can be used anytime and anywhere. As a result, the use of portable electronic devices such as mobile phones, digital cameras, and notebook computers has rapidly increased. These portable electronic devices generally use a memory system having memory device(s), that is, data storage device(s). The data storage device is used as a main memory device or an auxiliary memory device of the portable electronic devices. Data storage devices using memory devices provide excellent stability, durability, high information access speed, and low power consumption, since they have no moving parts. Examples of data storage devices having such advantages include universal serial bus (USB) memory devices, memory cards having various interfaces, and solid state drives (SSD).

Memory systems can perform operations such as read and decoding operations on data stored therein. In this context, embodiments of the present invention arise.

### SUMMARY

Aspects of the present invention include a system and a method for read retry operations of a memory device.

In one aspect, there is provided a memory system comprising a memory device including at least one page for storing data, and a controller coupled to the memory device. The controller is configured to: perform multiple read operations on the data of the at least one page using a set of read voltages which includes a center read voltage and neighboring read voltages adjacent to the center read voltage, determine fail bit counts (FBCs) for the set of read voltages, determine gradients of FBCs between the center read voltage and the neighboring read voltages based on the determined FBCs, and adjust the neighboring read voltages and the center read voltage based on the gradients of FBCs to generate a set of adjusted read voltages including adjusted neighboring and center read voltages.

In another aspect, there is provided a method for operating a memory system. The method includes performing multiple read operations on data of at least one page of a memory device using a set of read voltages which includes a center read voltage and neighboring read voltages adjacent to the center read voltage; determining fail bit counts (FBCs) for the set of read voltages; determining gradients of FBCs between the center read voltage and the neighboring read voltages based on the determined FBCs; and adjusting the neighboring read voltages and the center read voltage based on the gradients of FBCs to generate a set of adjusted read voltages including adjusted neighboring and center read voltages.

Additional aspects of the present invention will become apparent from the following description.

### BRIEF DESCRIPTION OF THE DRAWINGS

FIG. 1 is a block diagram illustrating a data processing system.

FIG. 2 is a block diagram illustrating a memory system.

FIG. 3 is a circuit diagram illustrating a memory block of a memory device.

FIG. 4 is a diagram illustrating distributions of states for different types of cells of a memory device.

FIG. 5A is a diagram illustrating an example of Gray coding for a multi-level cell (MLC).

FIG. 5B is a diagram illustrating state distributions for pages of a multi-level cell (MLC).

FIG. 6A is a diagram illustrating one example of Gray coding for a triple-level cell (TLC).

FIG. 6B is a diagram illustrating state distributions for pages of a triple-level cell (TLC).

FIG. 7 is a diagram illustrating one example of Gray coding and state distributions for pages of a quadruple-level cell (QLC).

FIG. 8 is a diagram illustrating a flow of an error recovery algorithm in a memory system.

FIG. 9 is a diagram illustrating a memory system in accordance with one embodiment of the present invention.

FIG. 10 is a diagram illustrating a format of a codeword to be stored in a storage system in accordance with embodiments of the present invention.

FIG. 11 is a diagram illustrating an example of proactively managing read retry for a memory device in accordance with embodiments of the present invention.

FIG. 12 is a flowchart illustrating an operation of proactively managing read retry voltages for a memory device according to one embodiment of the invention.

### DETAILED DESCRIPTION

Various embodiments of the present invention are described below in more detail with reference to the accompanying drawings. The present invention may, however, be embodied in different forms and thus should not be construed as limited to the embodiments set forth herein. Rather, these embodiments are provided so that this disclosure conveys the scope of the present invention to those skilled in the art. Moreover, reference herein to “an embodiment,” “another embodiment,” or the like is not necessarily to only one embodiment, and different references to any such phrase are not necessarily to the same embodiment(s). The term “embodiments” as used herein does not necessarily refer to all embodiments. Throughout the disclosure, like reference numerals refer to like parts in the figures and embodiments of the present invention.

The present invention can be implemented in numerous ways, for example including as a process; an apparatus; a system; a computer program product embodied on a computer-readable storage medium; and/or a processor, such as a processor suitable for executing instructions stored on and/or provided by a memory coupled to the processor. In this specification, these implementations, or any other form that the present invention may take, may be referred to as techniques. In general, the order of the operations of disclosed processes may be altered within the scope of the present invention. Unless stated otherwise, a component such as a processor or a memory described as being suitable for performing a task may be implemented as a general device or circuit component that is configured or otherwise programmed to perform the task at a given time or as a specific device or as a circuit component that is manufactured or pre-configured or pre-programmed to perform the task. As used herein, the term ‘processor’ or the like refers to one or more devices, circuits, and/or processing cores suitable for processing data, such as computer program instructions.

The methods, processes, and/or operations described herein may be performed by code or instructions to be executed for example by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described herein, the code or instructions for implementing the operations of the method embodiments may transform the computer, processor, controller, or other signal processing device into a special-purpose processor for performing any one of the methods herein.

If implemented at least partially in software, the controllers, processors, devices, modules, units, multiplexers, generators, logic, interfaces, decoders, drivers, generators and other signal generating and signal processing features may include, for example, a memory or other storage device for storing code or instructions to be executed, for example, by a computer, processor, microprocessor, controller, or other signal processing device.

A detailed description of various embodiments of the present invention is provided below along with accompanying figures that illustrate aspects of the present invention. The present invention is described in connection with such embodiments, but the present invention is not limited to any specific embodiment. The present invention encompasses numerous alternatives, modifications and equivalents. Numerous specific details are set forth in the following description in order to provide a thorough understanding of the present invention. These details are provided for the purpose of example; the present invention may be practiced without some or all of these specific details. For clarity, technical material that is known in technical fields related to the present invention has not been described in detail so that the invention is not unnecessarily obscured.

Semiconductor memory devices may be volatile or nonvolatile. The volatile semiconductor memory devices perform read and write operations at high speeds, while contents stored therein may be lost at power-off. The nonvolatile semiconductor memory devices may retain contents stored therein even at power-off. The nonvolatile semiconductor memory devices may be used to store contents, which must be retained regardless of whether they are powered.

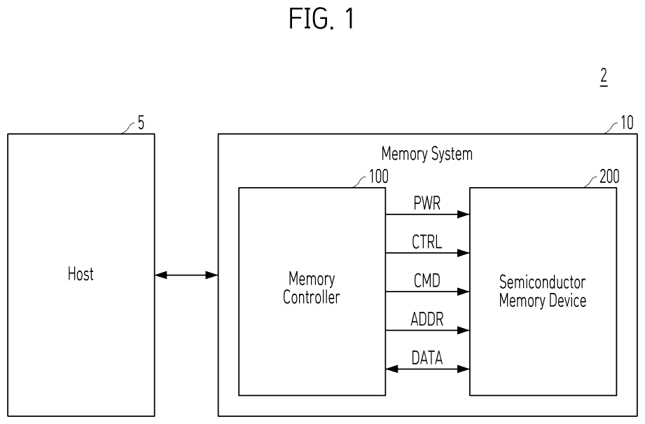

FIG. 1 is a block diagram illustrating a data processing system 2 in accordance with one embodiment of the present invention.

Referring FIG. 1, the data processing system 2 may include a host device 5 and a memory system 10. The memory system 10 may receive a request from the host device 5 and operate in response to the received request. For example, the memory system 10 may store data to be accessed by the host device 5.

The host device 5 may be implemented with any of various types of electronic devices. In various embodiments, the host device 5 may be an electronic device such as for example a desktop computer, a workstation, a three-dimensional (3D) television, a smart television, a digital audio recorder, a digital audio player, a digital picture recorder, a digital picture player, and/or a digital video recorder and a digital video player. In various embodiments, the host device 5 may be a portable electronic device such as for example a mobile phone, a smart phone, an e-book, an MP3 player, a portable multimedia player (PMP), and/or a portable game player.

The memory system 10 may be implemented with any of various types of storage devices such as a solid state drive (SSD) and a memory card. In various embodiments, the memory system 10 may be provided as one of various components in an electronic device such as for example a computer, an ultra-mobile personal computer (PC) (UMPC), a workstation, a net-book computer, a personal digital assistant (PDA), a portable computer, a web tablet PC, a wireless phone, a mobile phone, a smart phone, an e-book reader, a portable multimedia player (PMP), a portable game device, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage device of a data center, a device capable of receiving and transmitting information in a wireless environment, a radio-frequency identification (RFID) device, as well as one of various electronic devices of a home network, one of various electronic devices of a computer network, one of electronic devices of a telematics network, or one of various components of a computing system.

The memory system 10 may include a memory controller 100 and a semiconductor memory device 200. The memory controller 100 may control overall operations of the semiconductor memory device 200 including those of bit error rate reporting as detailed below.

The semiconductor memory device 200 may perform one or more erase, program, and read operations under the control of the memory controller 100. The semiconductor memory device 200 may receive through input/output lines a command CMD, an address ADDR and data DATA. The semiconductor memory device 200 may receive power PWR through a power line and a control signal CTRL through a control line. The control signal CTRL may include for example a command latch enable signal, an address latch enable signal, a chip enable signal, a write enable signal, a read enable signal, as well as other operational signals depending on design and configuration of the memory system 10.

The memory controller 100 and the semiconductor memory device 200 may be integrated in a single semiconductor device such as a solid state drive (SSD). The SSD may include a storage device for storing data therein.

The memory controller 100 and the semiconductor memory device 200 may be integrated in a single semiconductor device such as a memory card. For example, the memory controller 100 and the semiconductor memory device 200 may be integrated to configure a personal computer (PC) card of personal computer memory card international association (PCMCIA), a compact flash (CF) card, a smart media (SM) card, a memory stick, a multimedia card (MMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), and/or a universal flash storage (UFS).

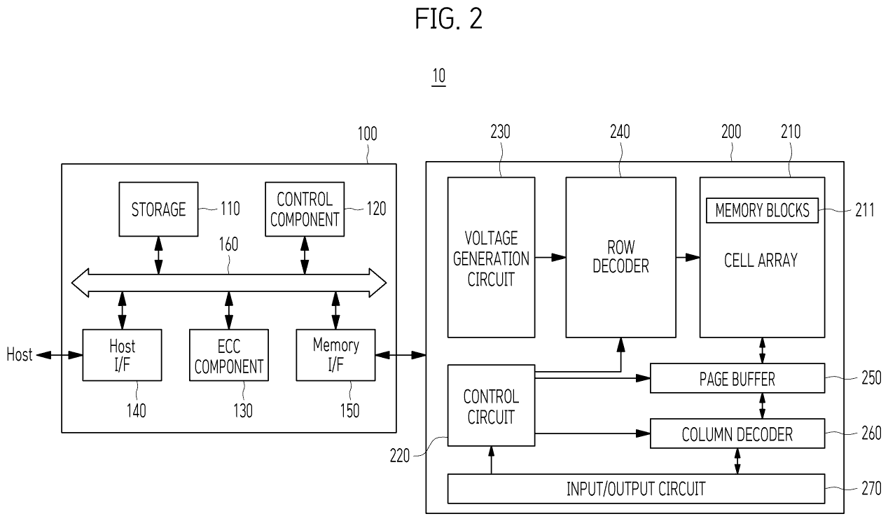

FIG. 2 is a block diagram illustrating a memory system in accordance with one embodiment of the present invention. For example, the memory system of FIG. 2 may depict the memory system 10 shown in FIG. 1.

Referring to FIG. 2, the memory system 10 may include a memory controller 100 and a semiconductor memory device 200. The memory system 10 may operate in response to a request from a host device (e.g., a request from host device 5 of FIG. 1), and in particular, store data to be accessed by the host device.

The memory device 200 may store data to be accessed by the host device.

The memory device 200 may be implemented with a volatile memory device such as for example a dynamic random access memory (DRAM) and/or a static random access memory (SRAM) or a non-volatile memory device such as for example a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), and/or a resistive RAM (RRAM).

The controller 100 may control storage of data in the memory device 200. For example, the controller 100 may control the memory device 200 in response to a request from the host device. The controller 100 may provide data read from the memory device 200 to the host device, and may store data provided from the host device into the memory device 200.

The controller 100 may include a storage 110, a control component 120, which may be implemented as a processor such as for example a central processing unit (CPU), an error correction code (ECC) component 130, a host interface (I/F) 140 and a memory interface (I/F) 150, which are coupled through a bus 160.

The storage 110 may serve as a working memory of the memory system 10 and the controller 100, and storage 110 may store data for driving the memory system 10 and the controller 100 The storage 110 may store data for encoding and/or decoding the data bit information being transmitted/received. For example, when the controller 100 controls operations of the memory device 200, the storage 110 may store data used by the controller 100 and the memory device 200 for such operations as read, write, program and erase operations, including encoding and decoding.

The storage 110 may be implemented with a volatile memory such as a static random access memory (SRAM) or a dynamic random access memory (DRAM). As described above, the storage 110 may store data used by the host device in the memory device 200 for the read and write operations. To store the data, the storage 110 may include a program memory, a data memory, a write buffer, a read buffer, a map buffer, and the like.

The control component 120 may control general operations of the memory system 10, and a write operation or a read operation for the memory device 200, in response to a write request or a read request from the host device. The control component 120 may drive firmware or other program instructions, which can be referred to as a flash translation layer (FTL), to control operations of the memory system 10. For example, the FTL may perform operations such as logical-to-physical (L2P) mapping, wear leveling, garbage collection, and/or bad block handling. The L2P mapping is known as logical block addressing (LBA).

The ECC component 130 may detect and correct errors in the data read from the memory device 200 during the read operation as detailed below. In one embodiment, the ECC component 130 may not correct error bits when the number of the error bits is greater than or equal to a threshold number of correctable error bits, but instead may output an error correction fail signal indicating failure in correcting the error bits.

In various embodiments, the ECC component 130 may perform an error correction operation based on a coded modulation such as for example a low density parity check (LDPC) code, a Bose-Chaudhuri-Hocquenghem (BCH) code, a turbo code, a turbo product code (TPC), a Reed-Solomon (RS) code, a convolution code, a recursive systematic code (RSC), a trellis-coded modulation (TCM), or a Block coded modulation (BCM). As such, the ECC component 130 may include any and all circuits, systems or devices suitable for error correction operation. In one embodiment of the present invention, a quasi-cyclic LDPC matrix (detailed below) is used for data recovery and bit error reporting.

The host interface 140 may communicate with the host device through one or more of various communication standards or interfaces such as for example a universal serial bus (USB), a multi-media card (MMC), a peripheral component interconnect express (PCI-e or PCIe), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The memory interface 150 may provide an interface between the controller 100 and the memory device 200 to allow the controller 100 to control the memory device 200 in response to a request from the host device. The memory interface 150 may generate control signals for the memory device 200 and process data under the control of the control component 120. In one embodiment where the memory device 200 is a flash memory such as a NAND flash memory, the memory interface 150 may generate control signals for the memory and process data under the control of the control component 120.

The memory device 200 as shown for example in FIG. 2 may include a memory cell array 210, a control circuit 220, a voltage generation circuit 230, a row decoder 240, a page buffer 250, which may be in the form of an array of page buffers, a column decoder 260, and an input and output (input/output) circuit 270. The memory cell array 210 may include a plurality of memory blocks 211 which may store data. The voltage generation circuit 230, the row decoder 240, the page buffer array 250, the column decoder 260 and the input/output circuit 270 may form a peripheral circuit for the memory cell array 210. The peripheral circuit may perform program, read, or erase operations of the memory cell array 210. The control circuit 220 may control the peripheral circuit.

The voltage generation circuit 230 may generate operational voltages of various levels. For example, in an erase operation, the voltage generation circuit 230 may generate operational voltages of various levels such as for example an erase voltage and a pass voltage.

The row decoder 240 may be in electrical communication with the voltage generation circuit 230, and the plurality of memory blocks 211. The row decoder 240 may select at least one memory block among the plurality of memory blocks 211 in response to a row address generated by the control circuit 220, and transmit operation voltages supplied from the voltage generation circuit 230 to the selected memory blocks.

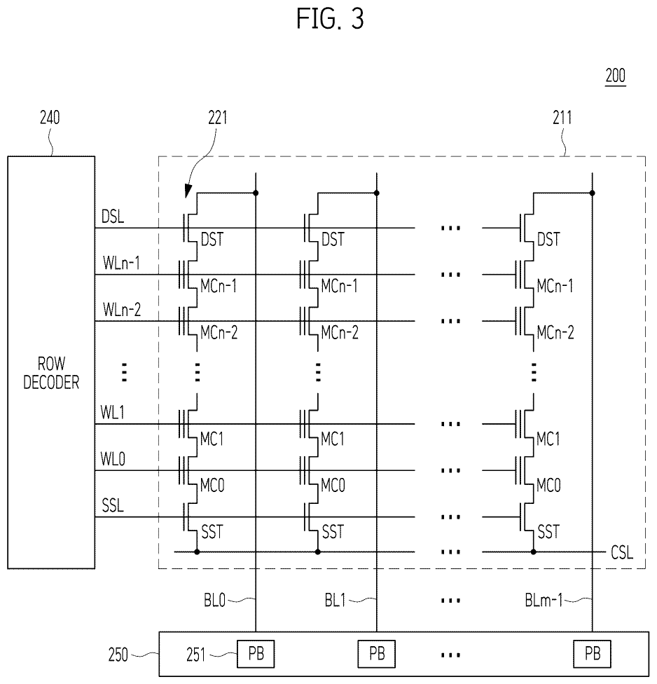

The page buffer 250 may be coupled with the memory cell array 210 through bit lines BL (shown in FIG. 3). The page buffer 250 may precharge the bit lines BL with a positive voltage, transmit data to, and receive data from, a selected memory block in program and read operations, or temporarily store transmitted data, in response to page buffer control signal(s) generated by the control circuit 220.

The column decoder 260 may transmit data to, and receive data from, the page buffer 250 or may transmit and receive data to and from the input/output circuit 270.

The input/output circuit 270 may transmit to the control circuit 220 a command and an address, received from an external device (e.g., the memory controller 100 of FIG. 1), transmit data from the external device to the column decoder 260, or output data from the column decoder 260 to the external device.

The control circuit 220 may control the peripheral circuit in response to the command and the address.

FIG. 3 is a circuit diagram illustrating a memory block of a semiconductor memory device in accordance with one embodiment of the present invention. For example, the memory block of FIG. 3 may be any of the memory blocks 211 of the memory cell array 210 shown in FIG. 2.

Referring to FIG. 3, the memory block 211 may include a plurality of word lines WL0 to WLn-1, a drain select line DSL and a source select line SSL coupled to the row decoder 240. These lines may be arranged in parallel, with the plurality of word lines between the DSL and SSL.

The memory block 211 may further include a plurality of cell strings 221 respectively coupled to bit lines BL0 to BLm-1. The cell string of each column may include one or more drain selection transistors DST and one or more source selection transistors SST. In the illustrated embodiment, each cell string has one DST and one SST. In a cell string, a plurality of memory cells or memory cell transistors MC0 to MCn-1 may be serially coupled between the selection transistors DST and SST. Each of the memory cells may be formed as a multiple level cell. For example, each of the memory cells may be formed as a single level cell (SLC) storing 1 bit of data. Each of the memory cells may be formed as a multi-level cell (MLC) storing 2 bits of data. Each of the memory cells may be formed as a triple-level cell (TLC) storing 3 bits of data. Each of the memory cells may be formed as a quadruple-level cell (QLC) storing 4 bits of data.

The source of the SST in each cell string may be coupled to a common source line CSL, and the drain of each DST may be coupled to the corresponding bit line. Gates of the SSTs in the cell strings may be coupled to the SSL, and gates of the DSTs in the cell strings may be coupled to the DSL. Gates of the memory cells across the cell strings may be coupled to respective word lines. That is, the gates of memory cells MC0 are coupled to corresponding word line WL0, the gates of memory cells MC1 are coupled to corresponding word line WL1, etc. The group of memory cells coupled to a particular word line may be referred to as a physical page. Therefore, the number of physical pages in the memory block 211 may correspond to the number of word lines.

The page buffer array 250 may include a plurality of page buffers 251 that are coupled to the bit lines BL0 to BLm-1. The page buffers 251 may operate in response to page buffer control signals. For example, the page buffers 251 my temporarily store data received through the bit lines BL0 to BLm-1 or sense voltages or currents of the bit lines during a read or verify operation.

In various embodiments of the present invention, the memory blocks 211 may include a NAND-type flash memory cell. However, the memory blocks 211 are not limited to such cell type, and may include NOR-type flash memory cell(s). Memory cell array 210 may be implemented as a hybrid flash memory in which two or more types of memory cells are combined, or one-NAND flash memory in which a controller is embedded inside a memory chip.

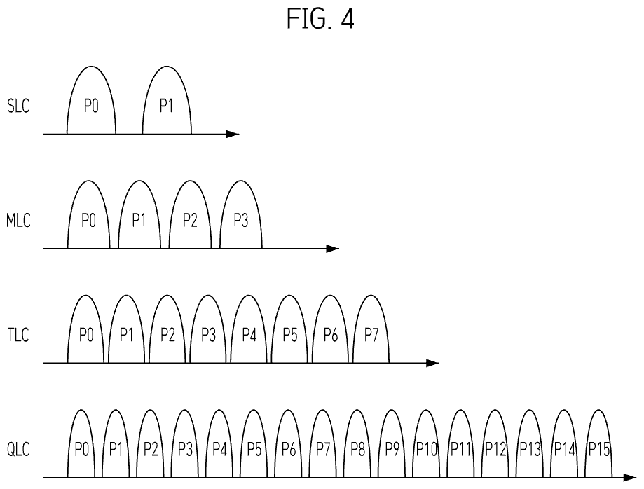

FIG. 4 is a diagram illustrating distributions of states or program voltage (PV) levels for different types of cells of a memory device.

Referring to FIG. 4, each of memory cells may be implemented with a specific type of cell, for example, a single level cell (SLC) storing 1 bit of data, a multi-level cell (MLC) storing 2 bits of data, a triple-level cell (TLC) storing 3 bits of data, or a quadruple-level cell (QLC) storing 4 bits of data. Usually, all memory cells in a particular memory device are of the same type, but that is not a requirement.

An SLC may include two states P0 and P1. P0 may indicate an erase state, and P1 may indicate a program state. Since the SLC can be set in one of two different states, each SLC may program or store 1 bit according to a set coding method. An MLC may include four states P0, P1, P2 and P3. Among these states, P0 may indicate an erase state, and P1 to P3 may indicate program states. Since the MLC can be set in one of four different states, each MLC may program or store two bits according to a set coding method. A TLC may include eight states P0 to P7. Among these states, P0 may indicate an erase state, and P1 to P7 may indicate program states. Since the TLC can be set in one of eight different states, each TLC may program or store three bits according to a set coding method. A QLC may include 16 states P0 to P15. Among these states, P0 may indicate an erase state, and P1 to P15 may indicate program states. Since the QLC can be set in one of sixteen different states, each QLC may program or store four bits according to a set coding method.

Referring back to FIGS. 2 and 3, the memory device 200 may include a plurality of memory cells (e.g., NAND flash memory cells). The memory cells are arranged in an array of rows and columns as shown in FIG. 3. The cells in each row are connected to a word line (e.g., WL0), while the cells in each column are coupled to a bit line (e.g., BL0). These word and bit lines are used for read and write operations. During a write operation, the data to be written (‘1’ or ‘0’) is provided at the bit line while the word line is addressed. During a read operation, the word line is again addressed, and the threshold voltage of each cell can then be acquired from the bit line. Multiple pages may share the memory cells that belong to (i.e., are coupled to) the same word line. When the memory cells are implemented with MLCs, the multiple pages include a most significant bit (MSB) page and a least significant bit (LSB) page. When the memory cells are implemented with TLCs, the multiple pages include an MSB page, a center significant bit (CSB) page and an LSB page. When the memory cells are implemented with QLCs, the multiple pages include an upper significant bit (USB) page, an MSB page, a CSB page and an LSB page. The memory cells may be programmed for example using a coding scheme (e.g., Gray coding) in order to increase the capacity of the memory system 10 such as SSD.

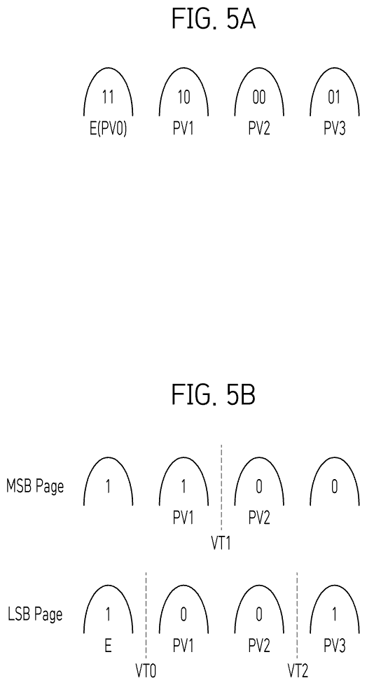

FIG. 5A is a diagram illustrating an example of coding for a multi-level cell (MLC).

Referring to FIG. 5A, an MLC may be programmed using a set type of coding. An MLC may have 4 program states, which include an erased state E (or PV0) and a first program state PV1 to a third program state PV3. The erased state E (or PV0) may correspond to “11.” The first program state PV1 may correspond to “10.” The second program state PV2 may correspond to “00.” The third program state PV3 may correspond to “01.”

In the MLC, as shown in FIG. 5B, there are 2 types of pages including LSB and MSB pages. 1 or 2 thresholds may be applied in order to retrieve data from the MLC. For an MSB page, the single threshold value is VT1. VT1 distinguishes between the first program state PV1 and the second program state PV2. For an LSB page, 2 thresholds include a threshold value VT0 and a threshold value VT2. VT0 distinguishes between the erased state E and the first program state PV1. VT2 distinguishes between the second program state PV2 and the third program state PV3.

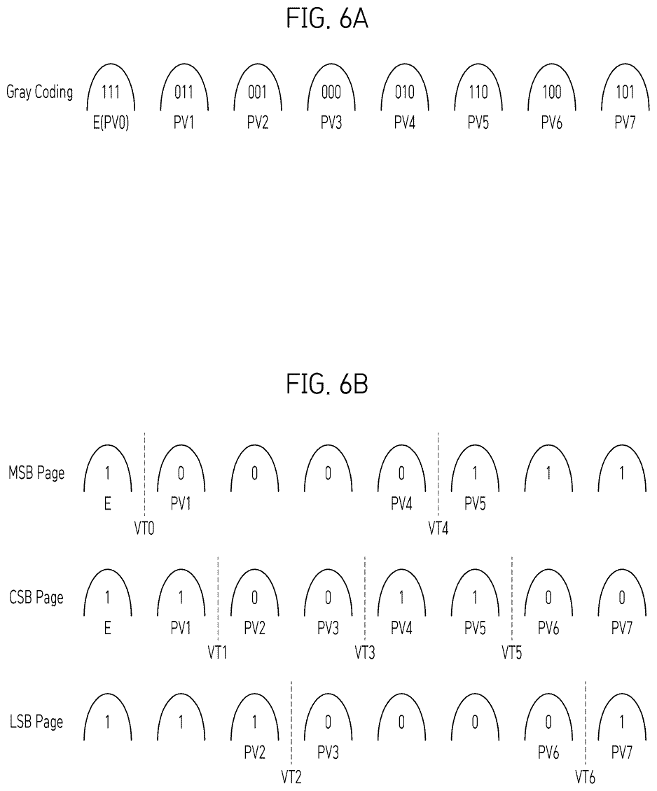

FIG. 6A is a diagram illustrating an example of Gray coding for a triple-level cell (TLC). FIG. 6B is a diagram illustrating state distributions for pages of a triple-level cell (TLC).

Referring to FIG. 6A, a TLC may be programmed using Gray coding. A TLC may have 8 program states, which include an erased state E (or PV0) and a first program state PV1 to a seventh program state PV7. The erased state E (or PV0) may correspond to “111.” The first program state PV1 may correspond to “011.” The second program state PV2 may correspond to “001.” The third program state PV3 may correspond to “000.” The fourth program state PV4 may correspond to “010.” The fifth program state PV5 may correspond to “110.” The sixth program state PV6 may correspond to “100.” The seventh program state PV7 may correspond to “101.”

In the TLC, as shown in FIG. 6B, there are 3 types of pages including LSB, CSB and MSB pages. 2 or 3 thresholds may be applied in order to retrieve data from the TLC. For an MSB page, 2 thresholds include a threshold value VT0 that distinguishes between an erased state E and a first program state PV1 and a threshold value VT4 that distinguishes between a fourth program state PV4 and a fifth program state PV5. For a CSB page, 3 thresholds include VT1, VT3 and VT5. VT1 distinguishes between a first program state PV1 and a second program state PV2. VT3 distinguishes between a third program state PV3 and the fourth program state PV4. VT5 distinguishes between the fourth program state PV5 and the sixth program state PV6. For an LSB page, 2 thresholds include VT2 and VT6. VT2 distinguishes between the second program state PV2 and the third program state PV3. VT6 distinguishes between the sixth program state PV6 and a seventh program state PV7.

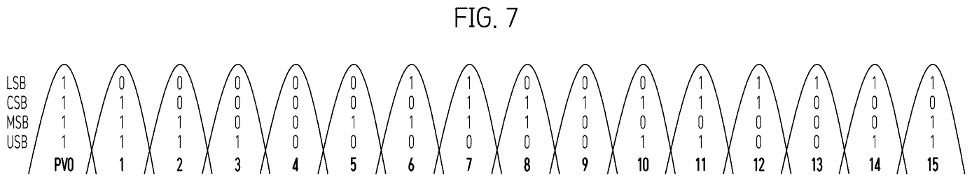

FIG. 7 is a diagram illustrating one example of Gray coding and state distributions for pages of a quadruple-level cell (QLC).

Referring to FIG. 7, a QLC may be programmed using Gray coding. A QLC may have 16 program states, which include an erased state PV0 (or E) and a first program state PV1 to a 15th program state PV15. The erased state PV0 may correspond to “1111.” The first program state PV1 may correspond to “0111.” The second program state PV2 may correspond to “0011.” The third program state PV3 may correspond to “0001.” The fourth program state PV4 may correspond to “0000.” The fifth program state PV5 may correspond to “0010.” The sixth program state PV6 may correspond to “1010.” The seventh program state PV7 may correspond to “1110.” The eighth program state PV8 may correspond to “0110.” The ninth program state PV9 may correspond to “0100.” The tenth program state PV10 may correspond to “0101.” The 11th program state PV11 may correspond to “1101.” The 12th program state PV12 may correspond to “1100.” The 13th program state PV13 may correspond to “1000.” The 14th program state PV14 may correspond to “1001.” The 15th program state PV15 may correspond to “1011.”

In the QLC, as shown in FIG. 7, there are 4 types of pages including LSB, CSB, MSB and USB pages. 3 or 4 thresholds may be applied in order to retrieve data from the QLC. For an USB page, 4 thresholds include a threshold value that distinguishes between a program state PV3 and a program state PV4, a threshold value that distinguishes between a program state PV9 and a program state PV10, a threshold value that distinguishes between a program state PV11 and a program state PV12, and a threshold value that distinguishes between a program state PV13 and a program state PV14. For an MSB page, 4 thresholds include a threshold value that distinguishes between a program state PV2 and a program state PV3, a threshold value that distinguishes between a program state PV4 and a program state PV5, a threshold value that distinguishes between a program state PV8 and a program state PV9, and a threshold value that distinguishes between a program state PV14 and a program state PV15. For a CSB page, 3 thresholds include a threshold value that distinguishes between a program state PV1 and a program state PV2, a threshold value that distinguishes between a program state PV6 and a program state PV7, and a threshold value that distinguishes between a program state PV12 and a program state PV13. For an LSB page, 4 thresholds include a threshold value that distinguishes between an erased state PV0 and a program state PV1, a threshold value that distinguishes between a program state PV5 and a program state PV6, a threshold value that distinguishes between a program state PV7 and a program state PV8, and a threshold value that distinguishes between a program state PV10 and a program state PV11.

After a memory array including a plurality of memory cells is programmed as described in FIGS. 5A, 6A and 7, when a read operation is performed on the memory array using a reference voltage such as a read threshold voltage (also called “read voltage level” or “read threshold”), the electrical charge levels of the memory cells (e.g., threshold voltage levels of transistors of memory cells) are compared to one or more reference voltages to determine the state of individual memory cells. When a specific read threshold is applied to the memory array, those memory cells that have threshold voltage levels higher than the reference voltage are turned on and detected as “on” cell, whereas those memory cells that have threshold voltage levels lower than the reference voltage are turned off and detected as “off” cell, for example. Therefore, each read threshold is arranged between neighboring threshold voltage distribution windows corresponding to different programmed states so that each read threshold can distinguish such programmed states by turning on or off the memory cell transistors.

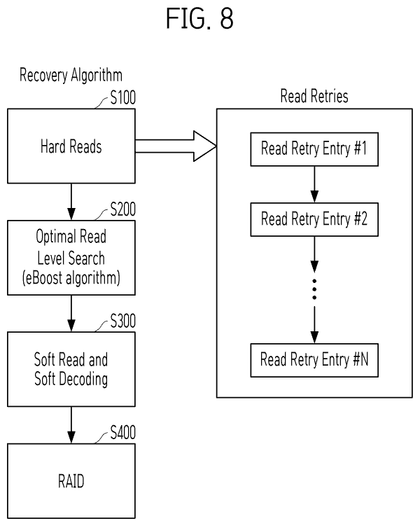

When a read operation is performed on memory cells in a data storage device, the threshold voltage levels of the memory cells are compared to more than one read threshold level to determine the state of individual memory cells. Read errors can be caused by distorted or overlapped threshold voltage distributions. An ideal memory cell threshold voltage distribution can change over time to be distorted or overlapped due to, e.g., program and erase (P/E) cycles, cell-to-cell interference, and/or data retention errors. For example, as program/erase cycles increase, the margin between neighboring threshold voltage distributions of different programmed states decreases and eventually the distributions overlap. As a result, the memory cells with threshold voltages that fall within the overlapping region of the neighboring distributions may be read as being programmed to a value other than the original targeted value and thus cause read errors. Such read errors may be managed in many situations by using error correction codes (ECC). When the number of bit errors on a read operation exceeds the ECC correction capability of the data storage, the read operation using a set read threshold voltage fails. The set read threshold voltage may be a previously used read threshold voltage (i.e., a historical read threshold voltage). The historical read threshold voltage may be the read threshold voltage used in the last successful decoding, that is, a read voltage used in a read-passed read operation performed before read retry operations. When the read operation using the set read threshold voltage failed, the controller 120 may control an error recovery algorithm such as for example the algorithm shown in FIG. 8.

Referring to FIG. 8, a controller (such as control component 120 in FIG. 2) may perform a sequence of hard reads to read data of a page (i.e., memory cells) using one or more hard read entries applied in a set order (S100). For example, the hard read entries may include N (e.g., N is 5 or 10) read threshold voltages (or read voltage levels) including a first read threshold voltage to an Nth read threshold voltage. The first read threshold voltage may be a previously used read threshold voltage (i.e., a history (historical) read threshold voltage). The historical read threshold voltage may be the read threshold voltage used in the last successful decoding, that is, a read voltage used in a read-passed read operation performed before the read retry operations. The controller 120 may perform the read retry operations until it is determined that decoding associated with a corresponding read retry operation is successful.

When all hard read retry operations using the N read threshold voltages have failed, the controller 120 may perform additional recovery operations. For example, the additional recovery operations may include an optimal read threshold voltage search (S200), a soft read and soft decoding using an error correction code (ECC) (S300) and/or a redundant array of independent disks (RAID) recovery (S400).

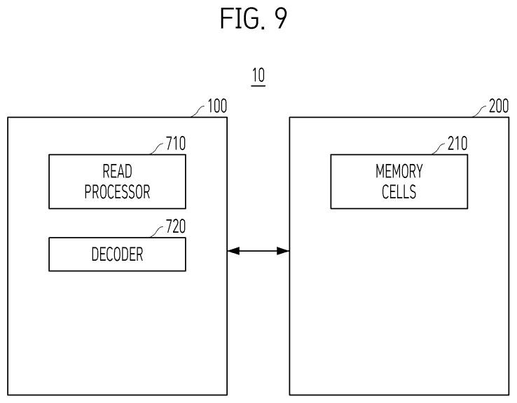

FIG. 9 is a diagram illustrating a memory system 10 in accordance with one embodiment of the present invention.

Referring to FIG. 9, the memory system 10 may include a controller 100 and a memory device 200. The memory device 200 may include a plurality of memory cells (e.g., NAND flash memory cells) 210. The memory cells are arranged in an array of rows and columns such as shown in FIG. 3. The cells in each row are connected to a word line (e.g., WL0), while the cells in each column are coupled to a bit line (e.g., BL0). These word and bit lines are used for read and write operations. During a write operation, the data to be written (‘1’ or ‘0’) is provided at the bit line while the word line is addressed. During a read operation, the word line is again addressed, and the threshold voltage of each cell can then be acquired from the bit line. Multiple pages may share the memory cells that belong to (i.e., are coupled to) the same word line. When the memory cells are implemented with MLCs, the multiple pages include a most significant bit (MSB) page and a least significant bit (LSB) page. When the memory cells are implemented with TLCs, the multiple pages include an MSB page, a center significant bit (CSB) page and an LSB page. When the memory cells are implemented with QLCs, the multiple pages include an USB page, an MSB page, a CSB page and an LSB page. The memory cells may be programmed using a coding scheme (e.g., Gray coding) in order to increase the capacity of the memory system 10 such as an SSD.

The controller 100 may include a read processor 710, and a decoder 720. Although it is illustrated that components of the controller 100 are implemented separately, these components may be implemented with an internal component (i.e., firmware (FW)) of the control component 120 in FIG. 2. The controller 100 and the memory device 200 may include various other components such as those shown in FIG. 2. Further, the controller 100 may include a media management processor 730 which is described later.

The read processor 710 may control one or more read operations for the memory device 200 in response to a read request from a host (e.g., the host 5 of FIG. 1). The read processor 710 may control the read operations using various read thresholds. The decoder 720 may decode data associated with the read operations.

In various embodiments of the present invention, the read processor 710 may control a read operation for the memory cells using a select read threshold from a set read level table. In various embodiments, the read level table may include multiple read thresholds and the select read threshold may include a default read threshold as described with reference to FIGS. 5B, 6B and 7.

In one embodiment of the present invention, it is determined whether the read operation using a read threshold selected from a read threshold set succeeded or failed, depending on the decoding result of the decoder 720. When the read operation using the selected read threshold failed, the read processor 710 may control one or more read retry operations for the memory cells using read retry entries.

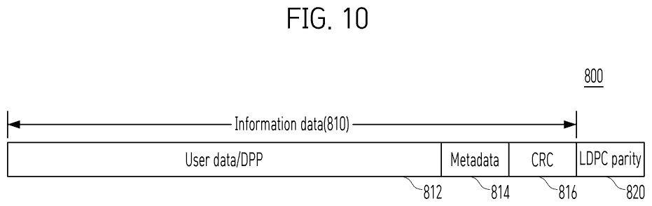

As background, FIG. 10 is a diagram illustrating a format of a codeword 800 to be stored in a storage system. Referring to FIG. 8, the codeword 800 may include information data 810 (information bits or user data) and LDPC parity data 820. In some embodiments, the codeword 800 may be generated by the LDPC codes noted above.

The information data 810 may include user data with data path protection (DPP) 812, meta-data 814 and cyclic redundancy check (CRC) parity bits 816. A CRC code which is an error-detecting code commonly used in digital networks and storage devices may detect accidental changes to raw data.

In a typical LDPC decoder, if the LDPC checksum is zero, the decoding may be terminated. The CRC parity bits 816 will be computed based on the decoded user data 812 and meta-data 814 after the LDPC decoding. If the computed CRC parity bits match the decoded CRC parity bits, decoding may be successful. Otherwise, a mis-correction may be declared.

As described above with reference to FIG. 8, when a read command is received from a host, a memory system (e.g., an SSD) uses a sequence of read retry entries to read and decode data of memory cells. Each read retry entry includes a different read bias. Vt optimization to find an optimal center read bias, and soft read and decoding using the optimal center read bias may also be performed when all hard read retry operations failed. Using additional reads or failed hard reads to adjust read retry entries can degrade a quality of service (QoS) of the memory system. Accordingly, embodiments of the present disclosure provide a proactive dynamic read retry scheme to proactively manage read retry entries for hard reads. The proactive dynamic read retry scheme uses a set of different read biases for a first read (hard read), which does not need additional reads. Thus, the read retry scheme can improve QoS of the memory system across different NAND conditions, even when conditions are changing constantly.

Referring back to FIG. 9, the controller 100 of the memory system 10, i.e., the read processor 710 may perform a sequence of hard reads (HRs) to read data stored in the memory cells 210 of the memory device 200. As illustrated in FIG. 8, N hard reads may be performed. For example, 5 hard reads (HRs) may be used (S100) before soft read is triggered (S300). The read biases (read retry entries) used in 5 hard reads may be defined as R0, R1, R2, R3 and R4. The number of hard read retry entries may be arbitrary.

### First Read Policy

The proactive dynamic read retry scheme may be performed by the read processor 710 using a first hard read (e.g., a read retry entry #1 of FIG. 8) without using additional hard reads other than a single read bias for each voltage threshold. The first hard read may use a set of different read biases including a center read bias (voltage) and neighboring read biases. In order to explore the neighborhood (i.e., neighboring read biases) of the center read bias, a gradient of fail bit count (FBC) of the center read bias may be calculated. Due to this calculation, the read processor 710 can detect in which direction the underlying optimal read threshold voltage (Vt) in each PV valley is moving. As shown in FIG. 6B, in a TLC NAND memory device, an LSB page has 2 valleys of (VT2, VT6), a CSB page has 3 valleys of (VT1, VT3, VT5), and an MSB page has 2 valleys of (VT0, VT4).

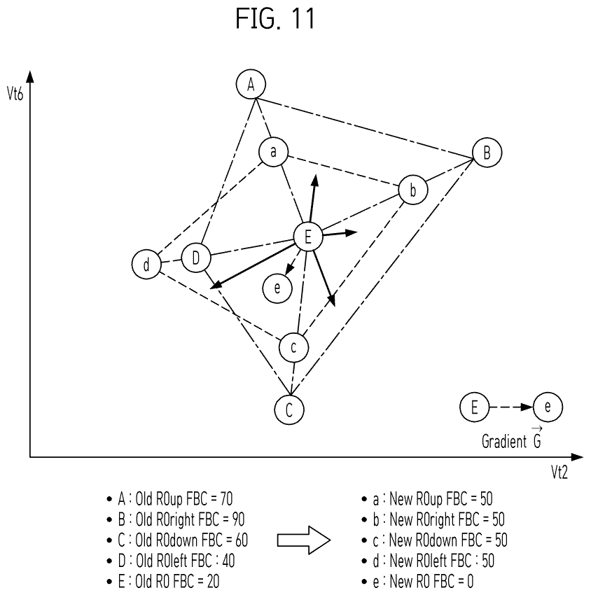

In some embodiments, for an LSB page in a TLC NAND, when R0 is the center read bias used for the first read, the set of first read biases can be denoted as R0S=[R0, R0left, R0right, R0up, R0down]. The terms “left,” “right,” “up” and “down” represent 4 different neighborhoods corresponding to 4 different directions from R0. In the illustrated example of FIG. 11, the center read bias is denoted by point E, and the neighboring read biases [R0left, R0right, R0up, R0down] denoted by other points displaced from point E, such as points a, b. c, d, A, B, C. D, etc., may be determined not to be aligned with X axis (Vt2 corresponding to VT2 of FIG. 6B) and Y axis (Vt6 corresponding to VT6 of FIG. 6B). In one example, for the LSB page, 2 neighbors around R0 may be sufficient to estimate the gradient of FBC with respect to Vt2 and Vt6. However, more neighbors may improve the accuracy of gradients between FBCs of the different points. For NAND and page types that have more valleys, the neighborhood can be defined in the similar way as above. During the first read, the read processor 710 may use the read biases in the set of read biases ROS in a round-robin way with the FBCs of the read biases compared in sequence from the center read bias or compared by a random selection.

The proactive dynamic read retry scheme allows the following quantities to be adapted on the fly:

(1) Fail Bit Counts (FBCs) may be produced from the set of read biases ROS. When a maximum FBC among the FBCs is greater than a threshold value, the center read bias entry R0 needs to be updated to adapt to the shift of optimal Vt. The threshold value may be determined as 90% of an ECC correctional capability.

(2) The rest read bias entries of ROS need to be adjusted to achieve the best gradient accuracy and minimize the risk of triggering a second hard read (e.g., the read retry entry #2 of FIG. 8).

(3) The entire read retry table (RRT) may be updated on the fly based on the shift of the center read bias entry R0.

### ROS Adaptation and Gradient Estimation

The set of read biases ROS may include a plurality of entries. In some embodiments, the number of the plurality of entries may be greater than or equal to the number of PV valleys. The neighbors of the center read bias R0 may be designed to cover a small neighborhood of a threshold voltage Vts about the center read bias R0 such that some meaningful gradient FBC information can be generated, for example on the fly without additional reads. If the set of read biases ROS, i.e., the number of the neighbors, is too large, there will be a risk that a read and decoding operation for the edge entries among the plurality of entries may fail and trigger a second read. If the number of the neighbors is too small, the gradient FBC information can be inaccurate.

The read processor 710 may control the size of the set of read biases ROS according to the FBC of the center read bias R0, and the FBC gradients produced from the entries of the set of read biases ROS. In some embodiments, the size of the set of read biases ROS may be controlled such that the maximum FBC from the set of read biases ROS is within the ECC correction capability with a certain margin.

FIG. 11 is a plot illustrating an example of proactively read retry management for a memory device in accordance with embodiments of the present invention. For example, FIG. 11 shows adaptation of read threshold voltages for a certain page, e.g., voltages [Vt2, Vt6] for an LSB page of a TLC NAND memory device. In some embodiments, the adaptation of read threshold voltages may be performed based on gradients of fail bit counts (FBCs). That is, the read retry management of FIG. 11 may include a FBC gradient calculation and adaptation of the set of read biases ROS, and may be performed by the controller 100 of FIG. 9.

In FIG. 11, points E, A, B, C and D represent coordinates of the read threshold voltages (Vt) of the set of read biases R0S=[R0, R0left, R0right, R0up, R0down]. The set of read biases ROS may include the center read voltage R0, and neighboring read voltages [R0left, R0right, R0up, R0down] as neighbors of the center read voltage. The neighbors of R0 may be designed to cover a small neighborhood of the Vts of R0 so that some meaningful gradient information can be generated to track the underlying shift of optimal Vt. The controller 100 may generate (produce) FBCs of the read threshold voltages of ROS. For example, a FBC for the center read voltage R0 is 20, a FBC for the center read voltage R0left is 70, a FBC for the center read voltage R0right is 90, a FBC for the center read voltage R0up is 40, and a FBC for the center read voltage R0down is 60. That is, FBC [20, 70, 90, 40, 60] represent the generated FBCs of the read threshold voltages of ROS.

The controller 100 may determine a maximum FBC among the generated FBCs, and compare the maximum FBC with a threshold value, e.g., 90% of an ECC correction capability (e.g., 90). When it is determined that the maximum FBC is less than the ECC correction capability and the maximum FBC is no less than a threshold, the controller 100 may determine that ROS and R0 needs to be adjusted or adapted. In order to adjust read threshold voltages, the controller 100 may calculate gradients of FBCs.

In the example above, the maximum FBC is 90 corresponding to the point B, and the ECC correction capability is 100. Let's also assume that when the maximum FBC produced by ROS is greater than or equal to 90 (i.e., max FBC>=90), gradient needs to be calculated and ROS and R0 needs to be adjusted. Since the maximum FBC is less than the ECC correction capability 100 and is no less than the threshold 90, the calculation of the gradients of FBCs is triggered. That is, the controller 100 may determine that gradients of FBCs need to be calculated and ROS and R0 needs to be adjusted. In some embodiments, the gradients of FBCs at the point E with respect to Vt2 and Vt6 may be calculated as follows.

### Gradient Calculation

The gradient of FBC with respect to Vt2 and Vt6 at R0 (or E) may be the sum of 4 gradients of FBCs between points A to E, between points B to E, between points C to E, and between points D to E:

$$\vec{G} = ( FBC ( A ) - FBC ( E ) ) * \frac{\vec{AE}}{\vert \vec{AE} \vert} + ( FBC ( B ) - FBC ( E ) ) * \frac{\vec{BE}}{\vert \vec{BE} \vert} + ( FBC ( C ) - FBC ( E ) ) * \frac{\vec{CE}}{\vert \vec{CE} \vert} + ( FBC ( D ) - FBC ( E ) ) * \frac{\vec{DE}}{\vert \vec{DE} \vert} = g \frac{\vec{Ee}}{\vert \vec{Ee} \vert} .$$

In the Equation, the first term represents

$$( FBC ( A ) - FBC ( E ) ) * \frac{\vec{AE}}{\vert \vec{AE} \vert}$$

represents a gradient between a FBC of the point A to a FBC of the point E, FBC (A) represents a FBC at the point A, FBC (E) represents a FBC at the point E, \vec{AE} represents a vector from A to E, |\vec{AE}| represents the length of vector \vec{AE}, ∥ represents the length of vector, and

$$\frac{\vec{AE}}{\vert \vec{AE} \vert}$$

represents the normalized vector from A to E. Similarly, the second to fourth terms are defined. The sum of gradients of FBCs may be represented as a vector addition.

### R0S Adaptation

The controller 100 may adjust neighboring points to point E such as points A, B, C and D on \vec{AE}, \vec{BE}, \vec{CE} and \vec{DE}, respectively, such that the neighbors all have some reasonable expected FBC, e.g., 50. The term “some reasonable” means that the expected FBC is not too small so that the gradient thereof is not accurate, nor the expected FBC is too large so that the risk of triggering a second read is high. For example, in FIG. 11, the point A has FBC=70 and the point E has FBC=20. The point A needs to move to the point a which is closer to the point E such that the expected FBC of the point a is equal to 50. The new Vt biases of A, B, C and D after the R0S adaptation are shown by the voltage values associated with points a, b, c and d.

### R0 Adaptation

With the gradient calculated, the controller 100 may move the point E to a new point e along the gradient \vec{G} such that the expected FBC will be zero (0). The length of \vec{Ee} can be calculated by FBC(R0)/g, where g represents the length of the gradient.

After the adaptation, the new read biases in R0S may be [e,a,b,c,d] and expected FBCs thereof may be [0,50,50,50,50] in this example. These new read biases will ensure that R0S is moving along with the underlying shift of optimal Vt so that the failure rate of the first read is minimized, and some good quality of the gradient is generated when needed. The term “some good quality” means that the new read biases in R0S can generate reasonable FBC. If the FBC is too small, the gradient is not accurate. If the FBC is too large, the risk of triggering second reads is high.

### Extension of the Proactive Dynamic Read Retry Scheme

In the illustrated embodiment of FIG. 11, the FBC of each point is used for the calculation for a FBC gradient. In other embodiments, an average FBC, for example, over n host reads (e.g., n=100) may be used. Using the average FBC can remove noise impact of the host reads and make the read retry scheme more robust.

In the illustrated embodiment of FIG. 11, all the read thresholds (e.g., Vt2 and Vt6) are updated simultaneously. In this embodiment, if each read threshold of a host read is biased towards the increasing direction of the FBC, the resulting FBC may be large enough to trigger a read defense flow (i.e., read and decoding operations) that can degrade the QoS of the host read.

To mitigate this issue, other embodiments may use a sequential read threshold update procedure by adapting only one read threshold each time by fixing the remaining read threshold(s). For example, for the case of FIG. 11, the Vt2 read threshold may be first adapted by fixing the Vt6 read threshold, and then the Vt6 read threshold may be adapted by fixing the Vt2 read threshold. This sequential read threshold update procedure can prevent the case that the FBC of some read biases is increased too much.

### Adaptation of RRT

The second and deeper entries (e.g., read retry entries #2 to #N of FIG. 8) in a read retry table (RRT) are designed to handle outliers, and it is a reasonable assumption that the outliers will also be influenced by the stress conditions in NAND, moving along with the majority of the pages in the block while roughly maintaining their relative distance to the center of the cloud. The term “outliers” means some pages with high FBC, and the term “cloud” means all the pages in the block. When the center read voltage R0 shifts from point E to point e, as shown in FIG. 11, this shift in one embodiment is applied to all other RRT entries (e.g., R1, R2, R3 and R4 corresponding to the read retry entries #2 to #N of FIG. 8), ensuring that the RRT entries adapt when NAND conditions change.

When soft read and decoding is triggered and successful, a newly found entry will replace R0 (let's refer to the old R0 as R0_old), and a new neighbor set R0S will be defined conservatively (not far from R0). The term “not far” means that the Euclidian distance from R0 is not large. In this situation, the worst entry should be evicted from R0_old, R1, R2, R3 and R4. One way to do this is by removing the entry with the longest Euclidian distance from R0. Another way is to remove the entry with the highest FBC.

### Computerized Method

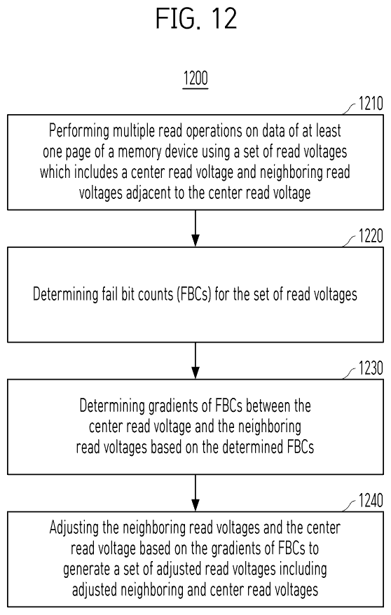

FIG. 12 is a flowchart illustrating an operation of proactively managing read retry voltages for a memory device according to one embodiment of the invention

In one embodiment of the present invention, there is provided a method 1200 in FIG. 12 for proactively managing read retry voltages according to one embodiment of the invention. The method 1200 may be performed by a memory system (e.g., the memory system 10 of FIG. 1), which includes a controller (e.g., the memory controller 100 of FIGS. 1 and 9) and a memory device (e.g., the semiconductor memory device 200 of FIGS. 1 and 9) including one or more pages (cells) for storing data. The method 1200 performed by the controller may be implemented with firmware (FW), e.g., the firmware of the control component 120 of the controller 100 in FIG. 2, or the read processor 710 and the decoder 720 of the controller 100 in FIG. 9.

Referring to FIG. 12, the method 1200 includes, at 1210, performing multiple read operations on data of at least one page of a memory device using a set of read voltages which includes a center read voltage and neighboring read voltages adjacent to the center read voltage. In some embodiments, the neighboring read voltages are in different directions from the center read voltage.

The operation 1220 includes determining fail bit counts (FBCs) for the set of read voltages. The operation 1230 includes determining gradients of FBCs between the center read voltage and the neighboring read voltages based on the determined FBCs. The operation 1240 includes adjusting the neighboring read voltages and the center read voltage based on the gradients of FBCs to generate a set of adjusted read voltages including adjusted neighboring and center read voltages.

In some embodiments, the method further includes using the set of adjusted read voltages to read the data of the at least one page.

In some embodiments, the method further includes determining whether a maximum FBC among the FBCs is greater than a threshold value. The determining of the gradients of FBCs includes determining the gradients of FBCs between the center read voltage and the neighboring read voltages when it is determined that the maximum FBC is no less than the threshold value.

In some embodiments, a size of the set of read voltages is determined based on the maximum FBC and the threshold value.

In some embodiments, the threshold value is determined based on an error correction code (ECC) correction capability.

In some embodiments, the adjusting of the neighboring read voltages and the center read voltage includes: generating the adjusted neighboring read voltages by moving the neighboring read voltages toward the center read voltage along the gradients of FBCs between the center read voltage and the neighboring read voltages, respectively.

In some embodiments, the adjusting of the neighboring read voltages and the center read voltage includes: generating the adjusted neighboring read voltages by moving the neighboring read voltages along the gradients of FBCs such that expected FBCs thereof are to be a set value, respectively.

In some embodiments, the method further includes determining a center gradient at the center read voltage by summing the gradients of FBCs.

In some embodiments, the adjusting of the neighboring read voltages and the center read voltage includes generating the adjusted center read voltage by moving the center read voltage along the center gradient.

In some embodiments, the adjusting of the neighboring read voltages and the center read voltage includes generating the adjusted center read voltage by moving the center read voltage along the center gradient such that an expected FBC thereof is to be zero.

Accordingly, embodiments of the present invention provide a proactive dynamic read retry scheme to proactively manage read retry entries for hard reads. The proactive dynamic read retry scheme uses a set of different read biases for a first read (hard read), which does not need additional reads. Thus, the read retry scheme can improve QoS of the memory system across different NAND conditions.

Although the foregoing embodiments have been described in some detail for purposes of clarity of understanding, the invention is not limited to the details provided. There are many alternative ways of implementing the invention. The disclosed embodiments are illustrative and not restrictive. The present invention is intended to embrace all modifications and alternatives of the disclosed embodiments. Furthermore, the disclosed embodiments may be combined to form additional embodiments.

Indeed, implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A memory system comprising:
a memory device including at least one page for storing data; and
a controller coupled to the memory device and configured to:
perform multiple read operations on the data of the at least one page using a set of read voltages which includes a center read voltage and neighboring read voltages adjacent to the center read voltage,
determine fail bit counts (FBCs) for the set of read voltages,
determine gradients of FBCs between the center read voltage and the neighboring read voltages based on the determined FBCs, and
adjust the neighboring read voltages and the center read voltage based on the gradients of FBCs to generate a set of adjusted read voltages including adjusted neighboring and center read voltages.

2. The memory system of claim 1, wherein the neighboring read voltages are in different directions from the center read voltage.

3. The memory system of claim 1, wherein the controller is further configured to use the set of adjusted read voltages to read the data of the at least one page.

4. The memory system of claim 1, wherein the controller is further configured to determine whether a maximum FBC among the FBCs is greater than a threshold value, and
wherein the controller is configured to determine the gradients of FBCs between the center read voltage and the neighboring read voltages when it is determined that the maximum FBC is no less than the threshold value.

5. The memory system of claim 4, wherein a size of the set of read voltages is determined based on the maximum FBC and the threshold value, and the threshold value is determined based on an error correction code (ECC) correction capability.

6. The memory system of claim 4, wherein the controller generates the adjusted neighboring read voltages by moving the neighboring read voltages toward the center read voltage based on the gradients of FBCs between the center read voltage and the neighboring read voltages, respectively.

7. The memory system of claim 6, wherein the controller generates the adjusted neighboring read voltages by moving the neighboring read voltages based on the gradients of FBCs such that expected FBCs thereof meet a set value.

8. The memory system of claim 6, wherein the controller is configured to determine a center gradient at the center read voltage by summing the gradients of FBCs.

9. The memory system of claim 8, wherein the controller generates the adjusted center read voltage by moving the center read voltage along the center gradient.

10. The memory system of claim 8, wherein the controller generates the adjusted center read voltage by moving the center read voltage along the center gradient such that an expected FBC thereof is zero.

11. A method for operating a memory system comprising:
performing multiple read operations on data of at least one page of a memory device using a set of read voltages which includes a center read voltage and neighboring read voltages adjacent to the center read voltage;
determining fail bit counts (FBCs) for the set of read voltages;
determining gradients of FBCs between the center read voltage and the neighboring read voltages based on the determined FBCs; and
adjusting the neighboring read voltages and the center read voltage based on the gradients of FBCs to generate a set of adjusted read voltages including adjusted neighboring and center read voltages.

12. The method of claim 11, wherein the neighboring read voltages are in different directions from the center read voltage.

13. The method of claim 11, further comprising: using the set of adjusted read voltages to read the data of the at least one page.

14. The method of claim 11, further comprising: determining whether a maximum FBC among the FBCs is greater than a threshold value, and
wherein the determining of the gradients of FBCs includes
determining the gradients of FBCs between the center read voltage and the neighboring read voltages when it is determined that the maximum FBC is no less than the threshold value.

15. The method of claim 14, wherein a size of the set of read voltages is determined based on the maximum FBC and the threshold value, and the threshold value is determined based on an error correction code (ECC) correction capability.

16. The method of claim 14, wherein the adjusting of the neighboring read voltages and the center read voltage includes:
generating the adjusted neighboring read voltages by moving the neighboring read voltages toward the center read voltage based on the gradients of FBCs between the center read voltage and the neighboring read voltages, respectively.

17. The method of claim 16, wherein the adjusting of the neighboring read voltages and the center read voltage includes:
generating the adjusted neighboring read voltages by moving the neighboring read voltages based on the gradients of FBCs such that expected FBCs thereof meet a set value.

18. The method of claim 16, further comprising: determining a center gradient at the center read voltage by summing the gradients of FBCs.

19. The method of claim 18, wherein the adjusting of the neighboring read voltages and the center read voltage includes:
generating the adjusted center read voltage by moving the center read voltage along the center gradient.

20. The method of claim 18, wherein the adjusting of the neighboring read voltages and the center read voltage includes:
generating the adjusted center read voltage by moving the center read voltage along the center gradient such that an expected FBC thereof is zero.
